(19) United States
(12) Patent Application Publication
(10) Pub. No.: US 2008/0105458 A1
(43) Pub. Date: May 8, 2008

(54) Substrate for mounting flip chip and the manufacturing method thereof

(75) Inventors: Myung-Sam Kang, Suwon-si (KR); Jung-Hyun Park, Suwon-si (KR); Sang-Duck Kim, Suwon-si (KR); Ji-Eun Kim, Gwangmyeong-si (KR); Jong-Gyu Choi, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/976,762

(22) Filed: Oct. 26, 2007

(30) Foreign Application Priority Data
Nov. 2, 2006 (KR) 10-2006-0107907

(51) Int. Cl. H05K 1/09; H05K 3/00

(52) U.S. Cl. 174/257; 29/842

(57) ABSTRACT

A substrate for mounting a flip chip and a method of manufacturing the substrate method of manufacturing the substrate are disclosed. Using a method of manufacturing a substrate for flip chip mounting that includes providing an insulating layer, in which a circuit pattern is buried, and forming at least one bump pad shaped as an indentation by removing at least one portion of the circuit pattern, the bumps pads can be formed by removing portions of a circuit pattern in the shape of indentations, to prevent solder bumps from flowing to the insulating layer portions and reduce the pitch between bumps.

### CROSS-REFERENCE TO RELATED APPLICATIONS

This application claims the benefit of Korean Patent Application No. 10-2006-0107907 filed with the Korean Intellectual Property Office on Nov. 2, 2006, the disclosure of which is incorporated herein by reference in its entirety.

### BACKGROUND

1. Technical Field

The present invention relates to a substrate for mounting a flip chip and a manufacturing method thereof.

2. Description of the Related Art

Flip chip mounting is a type of Chip Scale Package (CSP) and is a method of manufacturing a package by mounting conductive pads on the substrate, without using a lead frame between a semiconductor chip and the substrate of the chip package. Flip chip mounting has the benefits that the chip package is much smaller than that manufactured with wire bonding and that the phase difference in electrical signal between wires is reduced, and thus the flip chip mounting is being widely used, with its use expected to continue into the future.

Although the technology of manufacturing CSP's is currently centered on using wire bonding mounting, the demand for flip chip mounting is expected to increase, in order to cope with the trends of higher frequencies and thinner substrates. With more and more cases of flip chip mounting replacing wire bonding, the pads for flip chip mounting on a substrate is becoming narrower, and there is a need to maintain a constant amount of conductive paste needed for connection.

One type of flip chip mounting method used in the related art is the so-called “Super Juffit” method. In order to implement a flip chip connection, solder may need to be cohered on the pads of a substrate in correspondence to the positions of the bumps on the flip chip, and according to the related art, a circuit is designed utilizing the fact that, when the width of the outer layer circuit on the substrate is the same, coating small solder particles over the surface and applying heat cause ripple shapes in the circuit. By applying this Super Juffit method, a certain amount of solder may be cohered in the pad portions of the substrate to enable flip chip mounting.

However, with the method of the related art described above, the height of the flip chip mounting pads protruding from the substrate cannot be controlled with precision, and there is a limit to how much of the material can be supplied.

### SUMMARY

An aspect of the present invention aims to provide a substrate for mounting a flip chip and a method of manufacturing the substrate, in which bumps pads are formed by removing portions of a circuit pattern in the shape of indentations, to prevent solder bumps from flowing to the insulating layer portions and reduce the pitch between bumps, as well as to reduce deviations in height of the substrate.

One aspect of the invention provides a method of manufacturing a substrate for flip chip mounting that includes providing an insulating layer, in which a circuit pattern is buried, and forming at least one bump pad shaped as an indentation by removing at least one portion of the circuit pattern.

Forming the bump pad may be performed by applying an etching resist over the insulating layer such that a portion corresponding to the bump pad is exposed, forming the bump pad by etching the circuit pattern with an etchant, and removing the etching resist.

The method may be performed with a further operation of stacking a metal layer on the bump pad, while the metal layer may include at least one of tin (Sn), titanium (Ti), and gold (Ag).

The bump pad may be shaped as a curved indentation or a polygonal indentation, or may be of any of a variety of shapes. Before forming the bump pad, a further operation can be performed of applying a solder resist over a surface of the insulating layer such that a portion corresponding to the bump pad is exposed.

After forming the bump pad, an additional operation may be included of forming at least one bump on the at least one bump pad, to form solder bumps for flip chip mounting on the substrate. Here, the bump may be formed by providing solder paste in correspondence with the bump pad, and then melting the solder paste.

Another aspect of the invention provides a substrate for mounting a flip chip that includes an insulating layer, a circuit pattern buried in the insulating layer, and a bump pad shaped as an indentation formed by removing portions of the circuit pattern.

The bump pad can be etched in various shapes, for example the shape of a curved indentation or a polygonal pattern and so on. The bump pad may have a metal layer formed on the surface, which may include at least one of tin (Sn), titanium (Ti), and gold (Ag). By forming a bump on the bump pad, a substrate for flip chip mounting may be provided.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a substrate for mounting a flip chip according to an embodiment of the present invention.

FIG. 2, FIG. 3, FIG. 4, FIG. 5, and FIG. 6 are perspective views illustrating a process of manufacturing a substrate for mounting a flip chip according to an embodiment of the present invention.

FIG. 7 and FIG. 8 are perspective views illustrating possible shapes for a bump pad according to an embodiment of the present invention.

FIG. 9 is a plan view illustrating a substrate for mounting a flip chip according to an embodiment of the present invention.

### DETAILED DESCRIPTION

Certain embodiments of the invention will be described below in more detail with reference to the accompanying drawings, in which those components are rendered the same reference numeral that are the same or are in correspondence, regardless of the figure number, and redundant explanations are omitted.

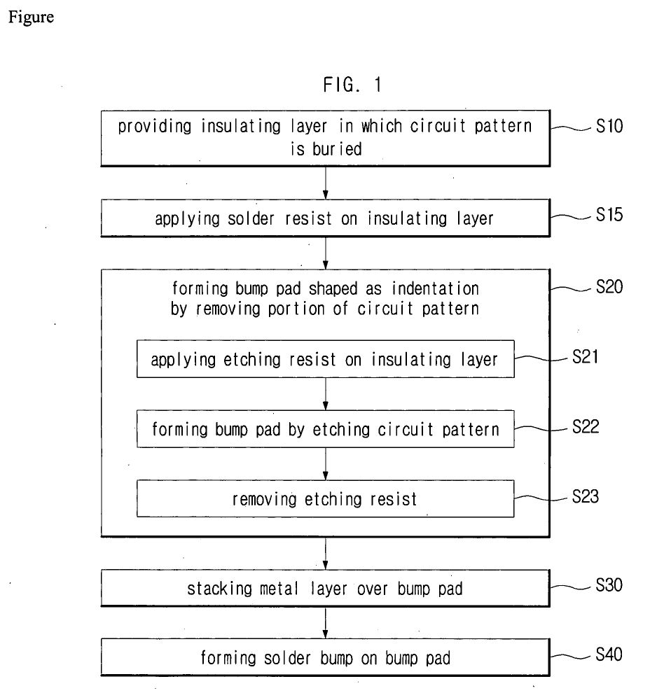

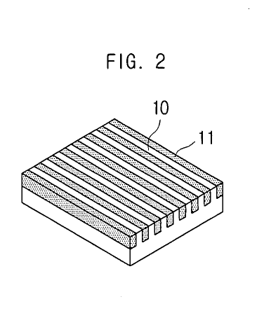

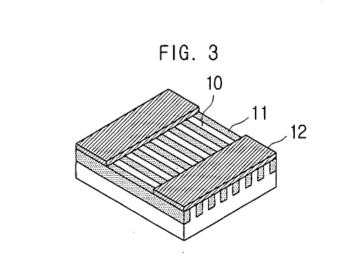

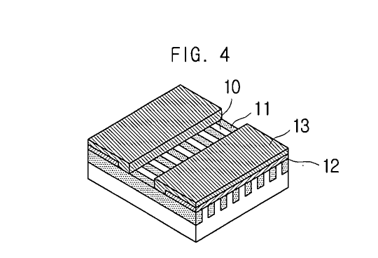

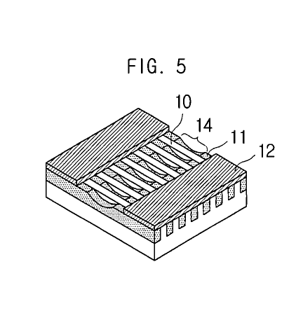

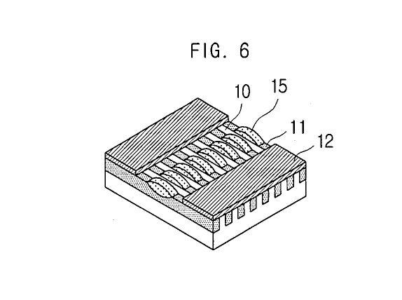

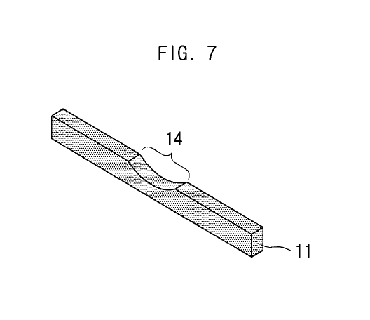

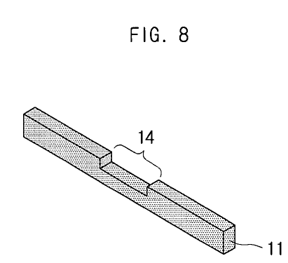

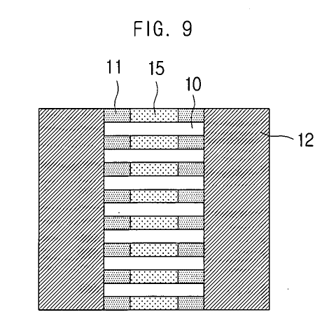

FIG. 1 is a flowchart illustrating a method of manufacturing a substrate for mounting a flip chip according to an embodiment of the present invention, FIG. 2 through FIG. 6 are perspective views illustrating a process of manufacturing a substrate for mounting a flip chip according to an embodiment of the present invention, FIG. 7 and FIG. 8 are perspective views illustrating possible shapes for a bump pad according to an embodiment of the present invention, and FIG. 9 is a plan view illustrating a substrate for mounting a flip chip according to an embodiment of the present invention.

Referring to the drawings, an insulating layer 10, a circuit pattern 11, solder resist 12, etching resist 13, bump pads 14, and solder bumps 15 are shown in FIG. 2 through FIG. 9.

Operation S10 of FIG. 1 may include providing an insulating layer in which a circuit pattern is buried.

FIG. 2 illustrates an insulating layer having a buried circuit pattern. This configuration of the circuit pattern 11 buried in the insulating layer 10 prevents the circuit pattern 11 from being peeled off, reduces errors in electrical connection, and enables the forming of a fine-pitch circuit, in comparison with a circuit pattern formed on the insulating layer.

Also, since there is no additional height incurred by the circuit pattern 11, there is the advantage of reducing deviations in the height of the substrate by lowering the height of the solder bumps 15. Here, the circuit pattern 11 buried in the insulating layer 10 may be made level with the height of the insulating layer 10.

Operation S20 may include removing portions of the circuit pattern 11 to form bump pads 14 shaped as indentations.

As a part of the circuit pattern 11, the bump pad 14 may be large in area such that solder paste may readily cohere on the bump pad 14. While bump pads 14 are generally used that are wider plane-wise than the circuit pattern 11, this may narrow the gaps between solder bumps 15, so that bridges may occur between the solder bumps 15. However, when the area of the bump pad 14 is increased by etching the circuit pattern, as in this embodiment, the area is increased depth-wise, so that the risk of bridges occurring between solder bumps 15 can be dramatically reduced.

An example of a method of removing portions of the circuit pattern is etching, where a bump pad 14 can be etched by performing the processes of S21 to S23.

Operation S21 is to apply etching resist 13 over the insulating layer. As an etchant may be supplied that is able to etch the circuit pattern 11, there is a risk that portions other than those where the bump pads 14 are to be formed may be etched and that the circuit pattern 11 may thus be damaged. Therefore, the circuit pattern 11 may be protected by coating etching resist 13, as in FIG. 4, such that only the portions corresponding to the bump pads 14 are exposed.

Operation S22 is to form the bump pads by supplying an etchant to etch the circuit pattern. An etchant capable of etching the circuit pattern 11 may be supplied to increase the area of the circuit pattern 11 in the depth direction and form the bump pads 14.

Operation S23 is to remove the etching resist 13. FIG. 5 illustrates the bump pads 14 with the etching resist 13 removed, after supplying an etchant to form the bump pads 14.

Of particular interest is that a substrate for flip chip connection can be manufactured without solder bridges occurring between solder bumps 15, even when the bump pads 14 are arranged in a row, and not in a zigzag arrangement. FIG. 2 through FIG. 6 and FIG. 9 illustrate examples in which the bump pads 14 are arranged in a row.

As shown in FIG. 7 and FIG. 8, the shape of the bump pads 14 may be curved, as in FIG. 7, or may be angled, as in FIG. 8. Of course, other shapes may be employed, as long as the bump pads 14 are etched to have a wide area.

Before proceeding with operation S20, an operation S15 may further be included, which is to coat a solder resist 12. The solder resist 12 may be coated on portions other than those portions where the solder is to be formed (referred to as lands or pads), so that the solder is applied only in the desired portions, and so that ultimately, solder bridges may be prevented.

As shown in FIG. 3, the solder resist 12 covers those portions other than the portions where the solder bumps 15 are to be formed. Because solder paste is not coated in those portions coated with the solder resist 12, the solder bumps 15 may be formed in the desired portions.

Depending on the amount of solder paste, the solder paste can be applied in portions other than the bump pads 14, but by using solder paste that is high in viscosity, or by controlling the amount of solder paste, the solder bumps 15 may be formed only on the bump pad 14 portions.

Operation S30 may include stacking a metal layer over the bump pads 14. In order for a solder bump to be formed exactly on the bump pad when the solder paste is melted, the bump pad may be covered with a metal layer, which generally uses at least one of tin (Sn), titanium (Ti), and gold (Ag). Operation S30 is not an essential part of the present invention and thus can be omitted.

Operation S40 may include forming solder bumps 15. After applying solder paste on the bump pads using a screen printing method, heat may be applied to the solder paste, and as the solder paste melts and becomes liquefied, the liquid solder may cohere due to surface tension. Here, as the areas of the bump pads 14 are wide, the solder may cohere in a convex manner, to form the solder bumps 15 when the solder is hardened.

In particular, according to this embodiment of the present invention, solder paste is prevented from overflowing to the insulating layer 10, and the problem of solder bridges is eliminated. FIG. 9 illustrates how the solder bumps 15 are not formed on the insulating layer 10 portions.

A substrate for mounting a flip chip according to certain embodiments of the present invention will be described below in more detail with reference to FIG. 7, FIG. 8 and FIG. 9.

A substrate for flip chip mounting is provided, which includes an insulating layer 10, a circuit pattern 11 buried in the insulating layer 10, and bump pads 14 shaped as indentations formed by removing portions of the circuit pattern.

As described above, when solder paste is melted, the fluid solder coheres in a convex shape on a wide area due to the surface tension of liquid. However, in this embodiment, instead of the conventional method of increasing the area width-wise, the area is increased depth-wise.

The bump pad can have various shapes, such as curved indentations or polygonal indentations, etc. To enhance the adhesion between the bump pads 14 and the solder paste, a metal layer of tin (Sn), titanium (Ti), or gold (Ag), etc., can be stacked on the bump pads 14, so that the solder bumps 15 may be formed on the bump pad 14 with greater accuracy.

A substrate for mounting a flip chip may be manufactured by adding solder bumps 15 onto the bump pads 14 described above. Because the circuit pattern is buried in the insulating layer and the bump pads 14 are etched depth-wise, the solder bumps can be formed only on the bump pads 14, and not on the insulating layer 10, as illustrated in FIG. 9.

According to certain embodiments of the invention as set forth above, a substrate for mounting a flip chip and a method of manufacturing the substrate are provided, in which bumps pads can be formed by removing portions of a circuit pattern in the shape of indentations, to prevent solder bumps from flowing to the insulating layer portions and reduce the pitch between bumps. Also, as the solder bumps may be formed on the bump pads formed by etching the circuit pattern, deviations in the height of the substrate can be reduced.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a substrate for mounting a flip chip, the method comprising:
providing an insulating layer having a circuit pattern buried therein; and
forming at least one bump pad shaped as an indentation by removing at least one portion of the circuit pattern.

2. The method of claim 1, wherein forming the bump pad comprises:
applying an etching resist over the insulating layer such that a portion corresponding to the bump pad is exposed;
forming the bump pad by etching the circuit pattern with an etchant; and
removing the etching resist.

3. The method of claim 1, further comprising:
stacking a metal layer on the bump pad.

4. The method of claim 3, wherein the metal layer contains at least one of tin (Sn), titanium (Ti), and gold (Ag).

5. The method of claim 1, wherein the bump pad is shaped as a curved indentation.

6. The method of claim 1, further comprising, before forming the bump pad:
applying a solder resist over a surface of the insulating layer such that a portion corresponding to the bump pad is exposed.

7. The method of claim 1, further comprising:
forming at least one solder bump on the at least one bump pad.

8. The method of claim 7, wherein forming the solder bump comprises:
providing solder paste on the bump pad; and
melting the solder paste.

9. A substrate for mounting a flip chip, the substrate comprising:
an insulating layer;
a circuit pattern buried in the insulating layer; and
a bump pad shaped as an indentation formed by removing at least one portion of the circuit pattern.

10. The substrate of claim 9, wherein the bump pad is etched in a shape of a curved indentation.

11. The substrate of claim 9, further comprising a metal layer stacked over a surface of the bump pad.

12. The substrate of claim 11, wherein the metal layer contains at least one of tin (Sn), titanium (Ti), and gold (Ag).

13. The substrate of claim 9, further comprising a solder bump formed on the bump pad.
